(19) United States
(12) Patent Application Publication
(10) Pub. No.: US 2022/0351991 A1
(43) Pub. Date: Nov. 3, 2022

(54) THINNED WAFER MANUFACTURING METHOD AND THINNED WAFER MANUFACTURING DEVICE

(71) Applicant: LINTEC CORPORATION, Tokyo (JP)

(72) Inventor: Naofumi IZUMI, Tokyo (JP)

(73) Assignee: LINTEC CORPORATION, Tokyo (JP)

(21) Appl. No.: 17/866,471

(22) Filed: Jul. 16, 2022

Related U.S. Application Data
(63) Continuation of application No. PCT/JP2021/001165, filed on Jan. 15, 2021.

(30) Foreign Application Priority Data
Jan. 27, 2020 (JP) 2020-011040

(51) Int. Cl. H01L 21/67; H01L 21/683; B24B 7/22

(52) U.S. Cl. CPC H01L 21/67132; H01L 21/67092; H01L 21/6835; B24B 7/228; B23K 26/53

(57) ABSTRACT

A device includes: a separating unit 10 which forms a weak layer WL in a semiconductor wafer WF supported by a base support unit BS to divide the wafer WF into a thinned wafer WF1 and a residual wafer WF2 with the weak layer WL as a boundary, and separates the wafer WF2 from the wafer WF1; a first transfer unit 20 which transfers the wafer WF1 from which the wafer WF2 is separated by the unit 10; a processing unit 30 which applies predetermined processing to the WF1 transferred by the unit 20; a second transfer unit 40 which transfers the wafer WF1 to which the predetermined processing is applied by the unit 30; and a reinforcing member pasting unit 50 which pastes a reinforcing member AS on the wafer WF1 transferred by the unit 40. The unit 20 and the unit 40 transfer the wafer WF1 with the unit BS.

### BACKGROUND OF THE INVENTION

### Field of the Invention

The present invention relates to a thinned wafer manufacturing method and a thinned wafer manufacturing device, and for example, relates to a method and a device to thin the original thickness of a semiconductor wafer.

### Description of the Related Art

Examples of a thinned wafer manufacturing method include a method to form a thinned wafer from a semiconductor wafer (hereinafter, also referred to simply as a “wafer”) by forming a weak layer in the wafer. This method divides one wafer into a lower-half wafer and an upper-half wafer and uses the upper-half wafer as the thinned wafer.

### SUMMARY OF THE INVENTION

The present invention disclosed and claimed herein, in one aspect thereof, comprises a thinned wafer manufacturing method. The method comprises:

a separating step of forming a weak layer in a semiconductor wafer supported by a base support unit to divide the semiconductor wafer into a thinned wafer and a residual wafer with the weak layer as a boundary, and separating the residual wafer from the thinned wafer;

a first transfer step of a first transfer unit transferring the thinned wafer from which the residual wafer is separated in the separating step, the thinned wafer being transferred with the base support unit;

a processing step of applying predetermined processing to the thinned wafer transferred in the first transfer step;

a second transfer step of a second transfer unit transferring the thinned wafer to which the predetermined processing is applied in the processing step, the thinned wafer being transferred with the base support unit; and

a reinforcing member pasting step of pasting a reinforcing member on the thinned wafer transferred in the second transfer step.

Further scope of applicability of the present invention will become apparent from the detailed description given hereinafter. The detailed description and embodiments are only given as examples though showing preferred embodiments of the present invention, and therefore, from the contents of the following detailed description, changes and modifications of various kinds within the spirits and scope of the invention will become apparent to those skilled in the art.

### BRIEF DESCRIPTION OF THE DRAWINGS

The present invention will be fully understood from the following detailed description and the accompanying drawings. The accompanying drawings only show examples and are not intended to restrict the present invention. In the accompanying drawings:

FIG. 1A is an explanatory view of a thinned wafer manufacturing device according to one embodiment;

FIG. 1B is an explanatory view of a modification example; and

FIG. 2A to FIG. 2D are explanatory views of the thinned wafer manufacturing device according to the embodiment.

### DETAILED DESCRIPTION

An embodiment of the present invention will be hereinafter described based on the drawings.

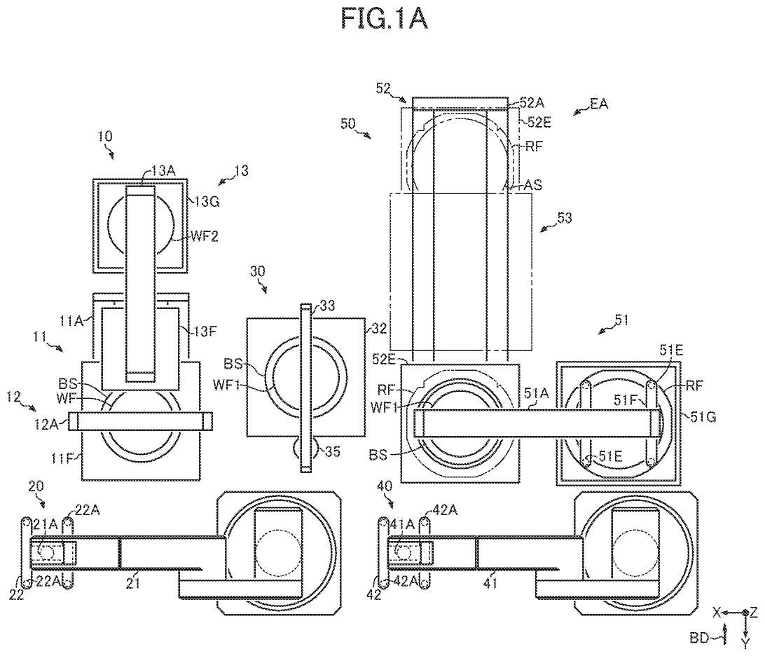

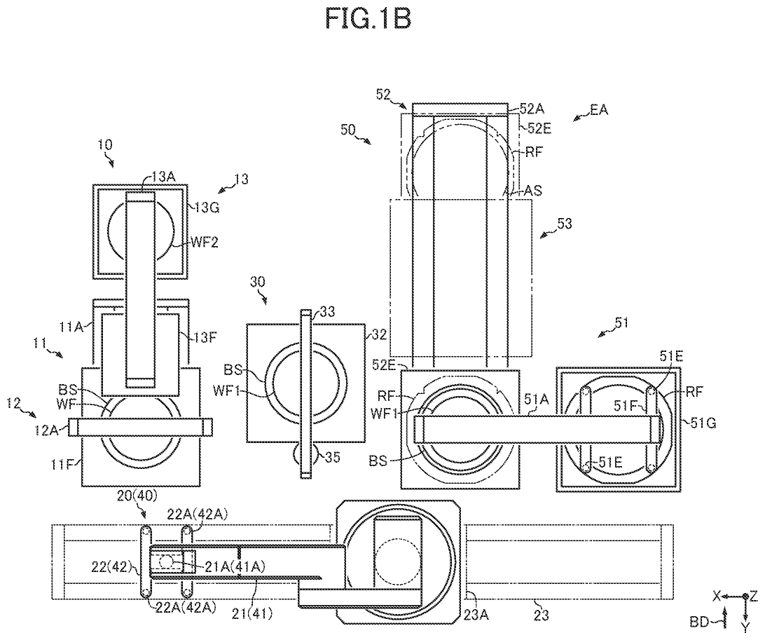

It should be noted that X-axis, Y-axis, and Z-axis in the embodiment are orthogonal to one another, where the X-axis and the Y-axis are within a predetermined plane while the Z-axis is orthogonal to the predetermined plane. Further, in the embodiment, FIG. 1A as viewed in the BD arrow direction parallel to the Y-axis is a reference for direction, and when a direction is mentioned without any designation of a drawing, an “upper” direction means a direction indicated by an arrow along the Z-axis, a “lower” direction means a direction opposite the upper direction, a “left” direction means a direction indicated by an arrow along the X-axis, a “right” direction means a direction opposite the “left” direction, a “front” direction means a direction toward the near side in FIG. 1A in terms of a direction parallel to the Y-axis, and a “rear” direction means a direction opposite the “front” direction.

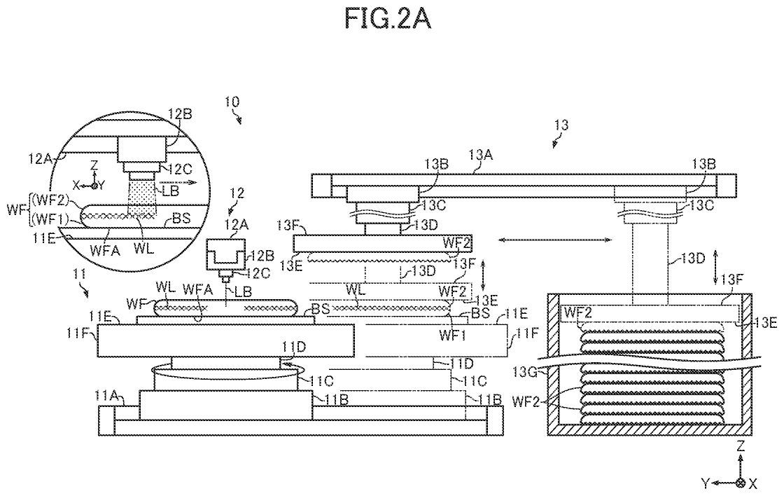

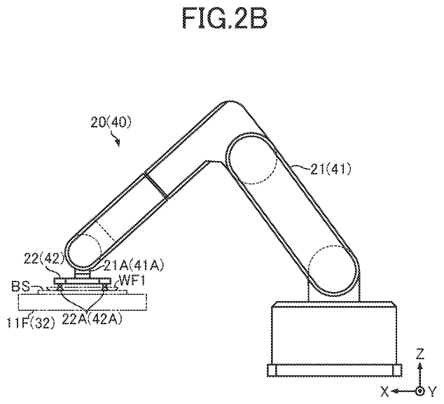

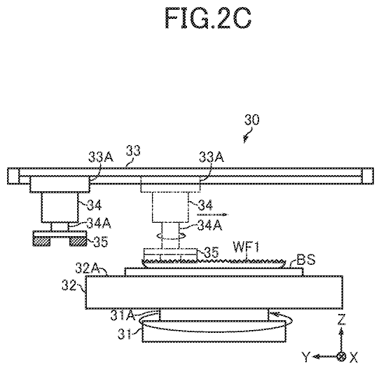

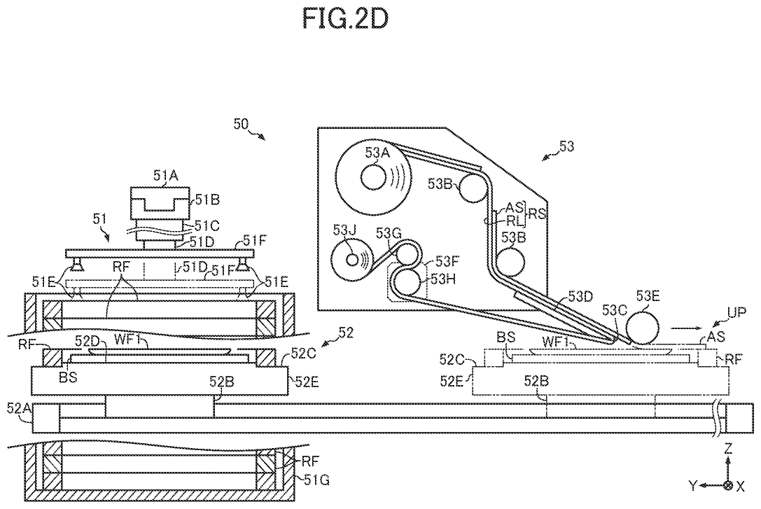

A thinned wafer manufacturing device EA includes: a separating unit which executes the step of forming a weak layer WL in a wafer WF supported by a base support unit BS to divide the wafer WF into a thinned wafer WF1 and a residual wafer WF2 with the weak layer WL as a boundary, and separating the residual wafer WF2 from the thinned wafer WF1; a first transfer unit 20 which executes the step of transferring the thinned wafer WF1 from which the residual wafer WF2 is separated by the separating unit 10; a processing unit 30 which executes the step of applying predetermined processing to the thinned wafer WF1 transferred by the first transfer unit 20; a second transfer unit 40 which executes the step of transferring the thinned wafer WF1 to which the predetermined processing is applied by the processing unit 30; and a sheet pasting unit 50 as a reinforcing member pasting unit which executes the step of pasting an adhesive sheet AS (see FIG. 2D) as a reinforcing member on the thinned wafer WF1 transferred by the second transfer unit 40.

The wafer WF has a not-illustrated predetermined circuit formed on its surface WFA, and the base support unit BS is pasted on the surface WFA with a not-illustrated energy ray-curable double-faced adhesive sheet as a support assisting material therebetween.

The separating unit 10 includes: a wafer support unit 11 which supports the wafer WF; a weak layer forming unit 12 which forms the weak layer WL in the wafer WF; and a residual wafer transfer unit 13 which transfers the residual wafer WF2.

The wafer support unit 11 includes: a rotary motor 11C as a drive device supported by a slider 11B of a linear motor 11A as a drive device; and a separation table 11F supported by an output shaft 11D of the rotary motor 11C and having a support surface 11E capable of suction-holding owing to a not-illustrated pressure-reducing unit (holding unit) such as a pressure-reducing pump or a vacuum ejector.

The weak layer forming unit 12 includes a laser irradiation device 12C supported by a slider 12B of a linear motor 12A as a drive device and capable of radiating laser beams LB. The laser irradiation device 12C sets its focal points to predetermined positions of the inside of the wafer WF to form the weak layer WL at the focal positions. In this embodiment, an output part of the laser irradiation device 12C is formed such that the plurality of focal points line up in the left-right direction.

The residual wafer transfer unit 13 includes: a direct-acting motor 13C as a drive device supported by a slider 13B of a linear motor 13A as a drive device; a suction table 13F supported by an output shaft 13D of the direct-acting motor 13C and having a suction surface 13E capable of suction-holding owing to a not-illustrated pressure-reducing unit (holding unit) such as a pressure-reducing pump or a vacuum ejector; and a recovery box 13G in which the residual wafer WF2 is recovered.

The first transfer unit 20 (second transfer unit 40) includes: what is called a multi-joint robot 21 (41) as a drive device including a plurality of arms and capable of displacing an object supported by its tip arm 21A (41A) as a working part to any position or any angle within its working range; and a transfer arm 22 (42) supported by the tip arm 21A (41A) and having a suction part 22A (42A) capable of suction-holding owing to a not-illustrated pressure-reducing unit (holding unit) such as a pressure-reducing pump or a vacuum ejector. The first transfer unit 20 (second transfer unit 40) transfers the thinned wafer WF1 with the base support unit BS, that is, transfers the thinned wafer WF1 in the state of being supported by the base support unit BS.

For the description of the configuration of the second transfer unit 40, the reference signs in the description of the configuration of the first transfer unit 20 are replaced with the parenthesized reference signs.

In this embodiment, the processing unit 30 polishes a weak layer WL-side surface of the thinned wafer WF1, and includes: a rotary motor 31 as a drive device; a processing table 32 supported by an output shaft 31A of the rotary motor 31 and having a support surface 32A capable of suction-holding owing to a not-illustrated pressure-reducing unit (holding unit) such as a pressure-reducing pump or a vacuum ejector; a linear and rotary motor 34 as a drive device supported by a slider 33A of a linear motor 33 as a drive device and capable of vertically and rotationally moving an output shaft 34A; and a polishing member 35 which is supported by the output shaft 34A and polishes the weak layer WL-side surface of the thinned wafer WF1.

The sheet pasting unit 50 includes: a frame transfer unit 51 which transfers a ring frame RF; a work support unit 52 which transfers the thinned wafer WF1 and the ring frame RF; and a sheet feed unit 53 which feeds the adhesive sheet AS to paste it.

The frame transfer unit 51 includes: a direct-acting motor 51C as a drive device supported by a slider 51B of a linear motor 51A as a drive device; a suction arm 51F supported by an output shaft 51D of the direct-acting motor 51C and having a suction part 51E capable of suction-holding owing to a not-illustrated pressure-reducing unit (holding unit) such as a pressure-reducing pump or a vacuum ejector; and a stocker 51G in which the ring frames RF are stocked.

The work support unit 52 includes: a pasting table 52E supported by a slider 52B of a linear motor 52A as a drive device, capable of supporting the ring frame RF on its frame mounting surface 52C, and having a support surface 52D capable of suction-holding owing to a not illustrated pressure-reducing unit (holding unit) such as a pressure-reducing pump or a vacuum ejector.

The sheet feed unit 53 includes: a support roller 53A which supports a raw sheet RS in which the adhesive sheets AS are temporarily bonded to a band-shaped release liner RL; a guide roller 53B which guides the raw sheet RS; a releasing plate 53D as a releasing unit which folds the release liner RL at its releasing edge 53C to release the adhesive sheet AS from the release liner RL; a press roller 53E as a press unit which presses the adhesive sheet AS against the ring frame RF and the thinned wafer WF1 to paste the adhesive sheet AS; a drive roller 53H which is supported by a not-illustrated output shaft of a rotary motor 53F as a drive device and sandwiches the release liner RL between itself and a pinch roller 53G; and a recovering roller 53J as a recovering unit which is supported by an output shaft of a not-illustrated drive device and constantly applies a predetermined tension to the release liner RL present between itself and the pinch roller 53G during the automatic operation of the thinned wafer manufacturing device EA, to recover the release liner RL.

The operation of the above-described thinned wafer manufacturing device EA will be hereinafter described.

First, a user of the thinned wafer manufacturing device EA (hereinafter, referred to simply as a “user”) sets the raw sheet RS as illustrated in FIG. 2D in the thinned wafer manufacturing device EA in which its members are arranged at the initial positions indicated by the solid lines in the drawings, and then inputs an automatic operation start signal through a not-illustrated operation unit such as an operation panel or a personal computer. In response, the sheet pasting unit 50 drives the rotary motor 53F to feed out the raw sheet RS, and when the feeding-direction leading end of the top adhesive sheet AS is released by a predetermined length at the releasing edge 53C of the releasing plate 53D, the sheet pasting unit 50 stops driving the rotary motor 53F. Next, when the user or a not-illustrated transfer unit such as a multi-joint robot or a belt conveyor places, on the separation table 11F, the wafer WF supported by the base support unit BS as illustrated in FIG. 2A, the separating unit 10 drives the not-illustrated pressure-reducing unit to start the suction-holding of the base support unit BS on the support surface 11E. Thereafter, the separating unit 10 drives the linear motor 11A to move the separation table 11F in the front-rear direction, and when the front-rear direction middle position of the wafer WF reaches the front-rear direction middle position of the laser irradiation device 12C in a side view seen in the X-axis direction, the separating unit 10 stops driving the linear motor 11A.

Next, the separating unit 10 drives the rotary motor 11C, the linear motor 12A, and the laser irradiation device 12C to move the laser irradiation device 12C from the outer edge side of the wafer WF toward its center while rotating the wafer WF. Consequently, the weak layer WL parallel to the XY plane is formed inside the wafer WF where the focal positions of the laser irradiation device 12C are present. Then, when the weak layer WL is formed all over the focal positions of the laser irradiation device 12C inside the wafer WF to divide the wafer WF into the thinned wafer WF1 and the residual wafer WF2, the separating unit 10 stops driving the rotary motor 11C and the laser irradiation device 12C, and thereafter drives the linear motor 12A to return the laser irradiation device 12C to the initial position.

Next, the separating unit 10 drives the linear motor 11A to move the separation table 11F rearward, and when the front-rear direction middle position of the wafer WF reaches the front-rear direction middle position of the suction table 13F in the side view, the separating unit 10 stops driving the linear motor 11A. Thereafter, the separating unit 10 drives the direct-acting motor 13C to bring the suction surface 13E into contact with the upper surface of the residual wafer WF2 as indicated by the two-dot chain line in FIG. 2A, and thereafter drives the not-illustrated pressure-reducing unit to start the suction-holding of the residual wafer WF2 on the suction surface 13E. Next, the separating unit 10 drives the linear motor 13A and the direct-acting motor 13C to lift the suction table 13F, thereby separating the residual wafer WF2 from the thinned wafer WF1, and thereafter, as indicated by the two-dot chain line in FIG. 2A, transfers the residual wafer WF2 into the recovery box 13G. Then, after stopping driving the not-illustrate pressure-reducing unit to cancel the suction-holding of the residual wafer WF on the suction surface 13E, the separating unit 10 drives the linear motor 13A and the direct-acting motor 13C to return the suction table 13F to the initial position, and at the same time, drives the linear motor 11A to return the separation table 11F to the initial position.

Next, the first transfer unit 20 drives the multi-joint robot 21 to bring the suction part 22A into contact with the upper surface of the base support unit BS supported by the separation table 11F, as indicated by the two-dot chain line in FIG. 2B, and thereafter drives the not-illustrated pressure-reducing unit to start the suction-holding of the base support unit BS on the suction part 22A. Thereafter, the separating unit 10 stops driving the not-illustrated pressure-reducing unit to cancel the suction-holding of the base support unit BS on the support surface 11E. Thereafter, the first transfer unit 20 drives the multi-joint robot 21 to place, on the processing table 32, the thinned wafer WF1 supported by the base support unit BS. Next, when the processing unit 30 drives the not-illustrated pressure-reducing unit to start the suction-holding of the base support unit BS on the support surface 32A, the first transfer unit 20 stops driving the not-illustrated pressure-reducing unit to cancel the suction-holding of the base support unit BS on the suction part 22A. Thereafter, the first transfer unit 20 drives the multi-joint robot 21 to return the transfer arm 22 to the initial position.

Then, the processing unit 30 drives the rotary motor 31, the linear motor 33, and the linear and rotary motor 34 to move the polishing member 35 which rotates from the outer edge side of the thinned wafer WF1 toward its center, while rotating the thinned wafer WF1, as indicated by the two-dot chain line in FIG. 2C. At this time, the processing unit 30 drives the linear and rotary motor 34 to adjust the height position of the polishing member 35 so that the thinned wafer WF1 comes to have a predetermined thickness. When the whole upper surface of the thinned wafer WF1 is polished, the processing unit 30 stops driving the rotary motor 31 and the linear and rotary motor 34, and thereafter drives the linear motor 33 and the linear and rotary motor 34 to return the polishing member 35 to the initial position.

Next, the second transfer unit 40 drives the multi-joint robot 41 to bring the suction part 42A into contact with the upper surface of the base support unit BS supported by the processing table 32, as indicated by the two-dot chain line in FIG. 2B, and thereafter drives the not-illustrated pressure-reducing unit to start the suction-holding of the base support unit BS on the suction part 42A. Thereafter, the processing unit 30 stops driving the not-illustrated pressure-reducing unit to cancel the suction-holding of the base support unit BS on the support surface 32A. Thereafter the second transfer unit 40 drives the multi-joint robot 41 to place, on the pasting table 52E, the thinned wafer WF1 supported by the base support unit BS, as illustrated in FIG. 2D. Next, when the sheet pasting unit 50 drives the not-illustrated pressure-reducing unit to start the suction-holding of the base support unit BS on the support surface 52D, the second transfer unit 40 stops driving the not-illustrated pressure-reducing unit to cancel the suction-holding of the base support unit BS on the suction part 42A, and thereafter drives the multi-joint robot 41 to return the transfer arm 42 to the initial position.

Then, the sheet pasting unit 50 drives the linear motor 52A to move the pasting table 52E in the front-rear direction, and when the front-rear direction middle position of the thinned wafer WF1 reaches the front-rear direction middle position of the suction arm 51F in the side view, the sheet pasting unit 50 stops driving the linear motor 52A. Next, the sheet pasting unit 50 drives the direct-acting motor 51C to bring the suction part 51E into contact with the upper surface of the ring frame RF present in the stocker 51G, as indicated by the two-dot chain line in FIG. 2D, and thereafter drives the not-illustrated pressure-reducing unit to start the suction-holding of the ring frame RF on the suction part 51E. Thereafter, when the sheet pasting unit 50 drives the linear motor 51A and the direct-acting motor 51C to place the suction-held ring frame RF on the frame mounting surface 52C, it stops driving the not-illustrate pressure-reducing unit to cancel the suction-holding of the ring frame RF on the suction part 51E, and thereafter drives the linear motor 51A and the direct-acting motor 51C to return the suction arm 51F to the initial position.

Next, the sheet pasting unit 50 drives the linear motor 52A to move the pasting table 52E rearward, and when the pasting table 52E reaches a predetermined position, the sheet pasting unit 50 drives the rotary motor 53F to feed out the raw sheet RS in pace with the moving speed of the pasting table 52E. Consequently, the adhesive sheet AS is released from the release liner RL, and the adhesive sheet AS released from the release liner RS is pressed against the ring frame RF and the thinned wafer WF1 by the press roller 53E to be pasted as indicated by the two-dot chain line in FIG. 2D. Then, the top adhesive sheet AS is entirely pasted on the ring frame RF and the thinned wafer WF1, so that a united product UP is formed. When the feeding-direction leading end of an adhesive sheet AS next to the top adhesive sheet AS is released by a predetermined length at the releasing edge 53C of the releasing plate 53D, the sheet pasting unit 50 stops driving the rotary motor 53F. Next, when the united product UP reaches a predetermined position at the rear of the press roller 53E, the sheet pasting unit 50 stops driving the linear motor 52A and thereafter stops driving the not-illustrated pressure-reducing unit to cancel the suction-holding of the base support unit BS on the support surface 52D. Thereafter, when the user or the not-illustrated transfer unit transfers the united product UP to the next step, the sheet pasting unit 50 drives the linear motor 52A to return the pasting table 52E to the initial position. Thereafter the same operation as above is repeated.

The thinned wafer WF1 transferred to the next step is sent to various devices such as a surface treating device which applies surface treatment to the thinned wafer WF1, a singulation device that singulates the thinned wafer WF1 by forming cuts in the thinned wafer WF1, and a cleaning device which cleans the thinned wafer WF1. Further, after the united product UP is removed from the pasting table 52E, the base support unit BS may be removed from the united product UP manually or with a not-illustrated removing unit. In the case where the base support unit BS is removed from the united product UP, in a pre-stage thereof, it is preferable to irradiate the not-illustrated energy ray-curable double-faced adhesive sheet with energy rays to reduce the adhesive strength of the not-illustrated double-faced adhesive sheet.

According to the above-described embodiment, the thinned wafer WF1 is protected by the base support unit BS in the steps until the adhesive sheet AS is pasted thereon, and even if the base support unit BS is removed, since the thinned wafer WF1 is protected by the adhesive sheet AS in the steps thereafter, it is possible to execute various steps on the thinned wafer WF1 without damaging the thinned wafer WF1.

The invention is by no means limited to the above units and processes as long as the above operations, functions or processes of the units and processes are achievable, still less to the above merely exemplary structures and processes described in the exemplary embodiment. For instance, the processing unit may be any as long as it is capable of processing the weak layer-side surface of the thinned wafer transferred by the first transfer unit and is not limited as long as it is within the technical scope at the time of the filing of the application (the same applies to the other units and steps).

The separating unit 10 may employ what is called an XY table or a multiaxial-direction moving unit such as a multi-joint robot capable of moving the separation table 11F or the suction table 13F in orthogonal two axial directions of the X and Y directions and directions including these components, to move the wafer WF in the XY plane or position the wafer WF and the thinned wafer WF1 when forming the weak layer WL in the wafer WF or when separating the residual wafer WF2 from the thinned wafer WF1. The laser irradiation device 12C of the separating unit 10 may be one whose focal points are dotted, linear, or planar. The separating unit 10 may employ, instead of the laser, one that applies, for example, electromagnetic wave, vibration, heat, chemicals, chemical substance, or the like to change the properties, characteristics, nature, material, composition, configuration, size, or the like, thereby forming the weak layer WL in the wafer WF. The weak layer WL may be one that is inclined relative to the XY plane, may be one capable of dividing the wafer WF into three sections or more, and may be one extending in the up-down direction or inclined relative to the up-down direction and having, for example, a lattice shape or other shape in a plan view so as to be capable of dividing the surface WFA into two or three sections or more. The weak layer WL may be one that makes the thinned wafer WF1 and the residual wafer WF2 completely apart from each other, or may be one that makes the thinned wafer WF1 and the residual wafer WF2 partially apart from each other. The thinned wafer WF1 and the residual wafer WF2 may be separated while or after they are relatively rotated along the plane of the weak layer WL, or may be separated while or after vibration is applied to the thinned wafer WF1 or the residual wafer WF2. In the case where the thinned wafer WF1 and the residual wafer WF2 are thus relatively rotated or the vibration is thus applied to the thinned wafer WF1 or the residual wafer WF2, the residual wafer transfer unit 13 side may be rotated or applies the vibration, or the wafer support unit 11 side may be rotated or applies the vibration.

The separating unit 10 may separate the residual wafer WF2 from the thinned wafer WF1 by bonding an adhesive body such as an adhesive sheet or a tacky sheet to the upper surface of the residual wafer WF2 and thereafter applying tension through the adhesive body, instead of using the suction table 13F.

The suction parts 22A, 42A of the first and second transfer units 20, 40 may suction-hold the thinned wafer WF1 or may suction-hold both the base support unit BS and the thinned wafer WF1. The first and second transfer units 20, 40 may be configured to employ a detecting unit, for example, an imaging unit such as a camera or a projector or any of various sensors such as an optical sensor or an ultrasonic sensor and place the wafer WF or the thinned wafer WF1 on the predetermined position of the separation table 11F, the processing table 32, or the pasting table 52E after positioning the wafer WF or the thinned wafer WF1 using the detecting unit.

The first transfer unit 20 may be one that places the wafer WF on the separation table 11F, or as illustrated in FIG. 1B, the first transfer unit 20 also works as the second transfer unit 40, and in this case, a slider 23A of a linear motor 23 may support the multi-joint robot 21 (41) to move the multi-joint robot 21 (41) as indicated by the two-dot chain line in FIG. 1B.

The processing unit 30 may be a polishing unit that performs chemical polishing, dry polishing, wet etching, dry etching, or the like, or may be a unit that performs any processing, for example, a grinding unit that grinds or splits the thinned wafer WF1, a coating unit that coats the thinned wafer WF1 with paint such as a protect material or a covering material, an applying unit that applies an additive such as an adhesive or a processed substance on the thinned wafer WF1, a plating unit that forms a metallic or nonmetallic coating film on the thinned wafer WF1, a laminating unit that laminates the thinned wafer WF1 with a laminate such as an adhesive sheet or a terminal (electrode), a cutting unit that cuts the thinned wafer WF1 by forming cuts therein, a singulation unit that singulates the thinned wafer WF1 by forming linear weak layers in the thinned wafer WF1 and applying tension to the thinned wafer WF1, and an expanding device that expands gaps between pieces formed by the singulation. The processing unit 30 may include one or two or more of the above units.

The sheet pasting unit 50 may be configured such that the frame mounting surface 52C is capable of suction-holding the ring frame RF owing to a not-illustrated pressure-reducing unit such as a pressure-reducing pump or a vacuum ejector. The ring frame RF as a frame member may be replaced by an annular or non-annular member, for instance. The raw sheet fed out by the sheet pasting unit 50 may be one in which cuts in a closed-loop shape or all along the short width direction are formed in a band-shaped adhesive sheet base temporarily bonded to the release liner RL and predetermined regions demarcated by the cuts are the adhesive sheets AS, or the sheet pasting unit 50 may employ a raw sheet in which a band-shaped adhesive sheet base is temporarily bonded to the release liner RL, and form cuts in a closed-loop shape or all along the short width direction by a cutting unit to set predetermined regions demarcated by the cuts as the adhesive sheets AS. The sheet pasting unit 50 may paste the band-shaped adhesive sheet base on the thinned wafer WF1 and the ring frame RF. When releasing the adhesive sheet AS from the release liner RL, the sheet pasting unit 50 may perform the torque control of the rotary motor 53F so that a predetermined tension is applied to the raw sheet RS. The raw sheet RS or the release liner RL may be supported or guided by a plate-shaped member, a shaft member, or the like instead of the rollers such as the support roller 53A and the guide roller 53B. The raw sheet RS may be supported in, for example, a fan-folded state instead of in a rolled-up state, to be drawn out. The sheet pasting unit 50 may employ a press unit that is supported by an output shaft of a direct-acting motor as a drive device, holds the adhesive sheet AS by its holding member capable of suction-holding owing to a not-illustrated pressure-reducing unit such as a pressure-reducing pump or a vacuum ejector, and presses the adhesive sheet AS held by the holding member against the thinned wafer WF1 and the ring frame RF to paste the adhesive sheet AS. The release liner RL may be recovered in, for example, a fan-folded state or in a state of being cut into small pieces by a shredder or the like instead of in the rolled-up state, or the release liner RL may be recovered simply in a piled-up state instead of in the rolled-up state or the fan-folded state. The recovery of the release liner RL may be omitted. The sheet pasting unit 50 may paste the adhesive sheet AS on the thinned wafer WF1 and the ring frame RF by moving the sheet feed unit 53 while moving or without moving the thinned wafer WF1 and the ring frame RF. The sheet pasting unit 50 may feed out an adhesive sheet AS to which the release liner RL is not temporarily bonded, to paste the adhesive sheet AS on the thinned wafer WF1 and the ring frame RF. At the time of the pasting of the adhesive sheet AS on the thinned wafer WF1 and the ring frame RF, the adhesive sheet AS may be turned upside down and may be set in landscape orientation.

The reinforcing member pasting unit may be configured to employ a hard member such as glass or an iron plate as the reinforcing member and paste the hard member on the thinned wafer WF1 with an adhesive unit such as a double-faced adhesive sheet or an adhesive therebetween, and in this case and if the adhesive sheet AS has appropriate rigidity, the frame transfer unit 51 need not be provided.

The wafer WF may have a circuit formed on at least one of the surface WFA and the other surface, or may have no circuit formed on the surface WFA or the other surface. The wafer WF may have a protect tape pasted on at least one of the surface WFA and the other surface or may have no protect tape pasted on the surface WFA or the other surface.

The base support unit BS may be any, for example, a hard member such as glass or an iron plate, a resin, or an adhesive sheet as long as it is capable of protecting the thinned wafer WF1, and for example, may be one that is capable of suction-holding owing to a not-illustrated pressure-reducing unit (holding unit) such as a pressure-reducing pump or a vacuum ejector similarly to the separation table 11F and the processing table 32, or may be one that is capable of holding owing to an electrostatic chuck. In this case, the support assisting member need not be provided.

The support assisting member may be a double-faced adhesive sheet of an energy ray-incurable type, or may be an adhesive or a tacky agent of an energy ray-curable type or an energy ray-incurable type.

The thinned wafer manufacturing device EA is capable of forming a thinned wafer also from the residual wafer WF2 separated from the thinned wafer WF1 by the separating unit 10, in which case, the processing unit 30 applies predetermined processing to the residual wafer WF2 and the sheet pasting unit 50 pastes the adhesive sheet AS on the residual wafer WF2 and the ring frame RF. What is needed in this case is that the residual wafer WF2 side is supported by a base support unit.

In the case where the thinned wafer manufacturing device EA forms the thinned wafer also from the residual wafer WF2, the thinned wafer manufacturing device EA may be configured such that the separating unit 10 forms the weak layer WL in the residual wafer WF2 to divide the residual wafer WF2 into a not-illustrated thinned wafer and a not-illustrated residual wafer with the weak layer WL as a boundary, and thereafter the adhesive sheet AS is pasted on the not-illustrated thinned wafer and a not-illustrated ring frame RF as in the above. What is needed in this case is also that the residual wafer WF2 side is supported by the base support unit.

It is not essential that the thinned wafer manufacturing device EA includes the not-illustrated removing unit. In the case where the protect tape is pasted on at least one of the surface WFA and the other surface, the thinned wafer manufacturing device EA may include a releasing unit that releases this protect tape.

The materials, types, shapes, and so on of the adhesive sheet AS, the wafer WF, the thinned wafer WF1, and the residual wafer WF2 in the present invention are not limited. For example, the adhesive sheet AS, the wafer WF, the thinned wafer WF1, and the residual wafer WF2 may be in a circular shape, an elliptical shape, a polygonal shape such as a triangular shape or a quadrangular shape, or any other shape. The adhesive sheet AS may be of a pressure-sensitive bonding type, a heat-sensitive bonding type, or the like. If the adhesive sheet AS is of the heat-sensitive bonding type, it may be bonded by an appropriate method, for example, by an appropriate heating unit for heating the adhesive sheet AS, such as a coil heater or a heating side of a heat pipe. Further, such an adhesive sheet AS may be, for example, a single-layer adhesive sheet having only an adhesive layer, an adhesive sheet having an intermediate layer between an adhesive sheet base and an adhesive layer, a three or more-layer adhesive sheet having a cover layer on the upper surface of an adhesive sheet base, or an adhesive sheet such as what is called a double-faced adhesive sheet in which an adhesive sheet base is releasable from an adhesive layer. The double-faced adhesive sheet may be one having one intermediate layer or more, may be a single-layer one or a multilayer one not having an intermediate layer. Further, the wafer WF, the thinned wafer WF1, and the residual wafer WF2 each may be, for example, a silicon semiconductor wafer or a compound semiconductor wafer. Note that the adhesive sheet AS may be read as one indicating its function or application, and may be, for example, any sheet, film, tape, or the like such as an information entry label, a decoration label, a protect sheet, a dicing tape, a die attach film, a die bonding tape, or a recording layer forming resin sheet.

The drive devices in the above-described embodiment each may be, for example, an electric machine such as a rotary motor, a direct-acting motor, a linear motor, a uniaxial robot, or a multi-joint robot having biaxial or triaxial or more joints, or may be an actuator such as an air cylinder, a hydraulic cylinder, a rodless cylinder, or a rotary cylinder. One in which some of these are directly or indirectly combined can also be employed.

In the above-described embodiment, in the case where a rotating member such as a roller is employed, a drive device that drives the rotation of the rotating member may be provided, and the surface of the rotating member or the rotating member itself may be formed of a deformable member such as rubber or resin or the surface of the rotating member or the rotating member itself may be formed of a non-deformable member. A member that rotates or does not rotate, such as a shaft or a blade, may be employed instead of the roller. In the case where one that presses an object to be pressed, such as a press unit or a press member such as a press roller or a press head, is employed, a member such as a roller, a round bar, a blade member, rubber, resin, or sponge may be employed or a structure that sprays gaseous substance such as the atmospheric air or gas for pressing may be employed, instead of or in addition to those exemplified in the above, and the one that presses may be formed of a deformable member such as rubber or resin or may be formed of a non-deformable member. In the case where one that releases an object to be released, such as a releasing unit or a releasing member such as a releasing plate or a releasing roller, is employed, a member such as a plate-shaped member, a round bar, or a roller may be employed instead of or in addition to those exemplified above, and the one that releases may be formed of a deformable member such as rubber or resin or may be formed of a non-deformable member. In the case where one that supports (holds) a member to be supported (member to be held), such as a support (holding) unit or a support (holding) member, is employed, the member to be supported may be supported (held) by a gripping unit such as a mechanical chuck or a chuck cylinder, Coulomb force, an adhesive (adhesive sheet, adhesive tape), a tackiness agent (tacky sheet, tacky tape), magnetic force, Bernoulli suction, suction attraction, a drive device, or the like. In the case where one that cuts a member to be cut or that forms a cut or a cutting line in a member to be cut, such as a cutting unit or a cutting member, is employed, one that cuts using a cutter blade, a laser cutter, ion beams, thermal power, heat, water pressure, a heating wire, or the spraying of gas, liquid, or the like may be employed instead of or in addition to those exemplified above, and at the time of the cutting, an appropriate combination of drive devices may move the one that cuts the object to be cut.

What is claimed is:

1. A thinned wafer manufacturing method comprising:
a separating step of forming a weak layer in a semiconductor wafer supported by a base support unit to divide the semiconductor wafer into a thinned wafer and a residual wafer with the weak layer as a boundary, and separating the residual wafer from the thinned wafer;
a first transfer step of a first transfer unit transferring the thinned wafer from which the residual wafer is separated in the separating step, the thinned wafer being transferred with the base support unit;
a processing step of applying predetermined processing to the thinned wafer transferred in the first transfer step;
a second transfer step of a second transfer unit transferring the thinned wafer to which the predetermined processing is applied in the processing step, the thinned wafer being transferred with the base support unit; and
a reinforcing member pasting step of pasting a reinforcing member on the thinned wafer transferred in the second transfer step.

2. The method of claim 1, wherein the first transfer unit also works as the second transfer unit.

3. A thinned wafer manufacturing device comprising:
a separating unit which forms a weak layer in a semiconductor wafer supported by a base support unit to divide the semiconductor wafer into a thinned wafer and a residual wafer with the weak layer as a boundary, and separates the residual wafer from the thinned wafer;
a first transfer unit which transfers the thinned wafer from which the residual wafer is separated by the separating unit, the thinned wafer being transferred with the base support unit;
a processing unit which applies predetermined processing to the thinned wafer transferred by the first transfer unit;
a second transfer unit which transfers the thinned wafer to which the predetermined processing is applied by the processing unit, the thinned wafer being transferred with the base support unit; and
a reinforcing member pasting unit which pastes a reinforcing member on the thinned wafer transferred by the second transfer unit.

4. The device of claim 3, wherein the first transfer unit also works as the second transfer unit.
